(19) United States
(12) Patent Application Publication
(10) Pub. No.: US 2009/0103396 A1
(43) Pub. Date: Apr. 23, 2009

(54) Information Input Apparatus Using Ultrasonic Waves and Position Recognition Method Thereof

(76) Inventor: Jong-Bum Seo, Incheon (KR)

Correspondence Address: HARNESS, DICKEY & PIERCE, P.L.C., P.O. BOX 8910, RESTON, VA, 20195, US

(21) Appl. No.: 11/920,557

(22) PCT Filed: Sep. 6, 2005
(86) PCT No.: PCT/KR2005/002938

§ 371 Date: Nov. 16, 2007

(30) Foreign Application Priority Data
May 26, 2005 (KR) 10-2005-0044592

(51) Int. Cl. G01S 3/80; H03K 17/94

(52) U.S. Cl. 367/127; 341/34

(57) ABSTRACT

The present invention relates to an input apparatus, and more particularly, to an information input apparatus and position recognition apparatus using an ultrasonic wave. The information input apparatus includes an input unit for generating an ultrasonic signal and a receiver for receiving the ultrasonic signal generated in the input unit, wherein the input unit includes ultrasonic generator for generating an ultrasonic signal according to a movement of the input unit, and a controller for generating a control signal to enable the ultrasonic generator to generate the ultrasonic waves, the receiver includes an ultrasonic receiver for receiving the ultrasonic signal generated in the ultrasonic generator, and a signal processor for performing a signal processing in a phase sensitive cross-correlation scheme in order to track the position of the input unit using the ultrasonic signal received in the ultrasonic receiver.

### TECHNICAL FIELD

The present invention relates to an input apparatus, and more particularly, to an information input apparatus using ultrasonic waves among input apparatuses capable of recognizing what a user has personally drawn or written, and a position recognition method thereof.

### BACKGROUND ART

On reviewing a computer input apparatus among input apparatuses, generally, the computer has input apparatuses such as a key board and a mouse, and output apparatuses such as a monitor and a printer, both apparatuses being connected to the computer. Further, the computer can be connected to many peripherals which perform many functions. Such peripherals include a speaker outputting sound in the computer, a DVD-ROM drive driving a DVD title in which a movie or multimedia data is stored, etc.

As such, the computer peripherals are diverse according to their purposes, wherein the input apparatuses are also diverse, including a key board or a mouse, a microphone to input a user's voice, a scanner to read a picture or a photo using a computer, a touch screen to input a position with a hand touch, a digitizer which is usually in CAD or a graphic design since it can be used as a pencil.

The computer is so diverse that the user can precisely input data or information into the computer according to a user's intension. For example, the key board has keys assigned to characters, numerals or specific signs, so it is possible to input them when the user pushes corresponding keys.

However, such a key board has a problem in that it is difficult for the user to input arbitrary type of data or information, such as a curve, and to move a point on a monitor screen to a desired position. So, an input apparatus of a mouse appeared to solve such a problem, which can input data or information indicating an arbitrary type. However, such a mouse cannot precisely input data or information so that there has appeared an input apparatus such as a digitizer to solve it.

Meanwhile, there is a computer input apparatus using ultrasonic waves among pen type computer input apparatuses which are similar to the digitizer, which generates the ultrasonic waves along the movement of the pen and recognizes the position. It will be described with reference to the accompanying drawings.

FIG. 1 is a view showing a pen type computer input apparatus using ultrasonic waves in the prior art.

Referring to FIG. 1, when a user moves a pen 10 including an ultrasonic generator 15 therein in a panel 20 having a predetermined size to which ultrasonic sensors 30 and 40 are attached, the ultrasonic generator 15 generates ultrasonic waves depending on a movement of the pen 10. The left and right ultrasonic sensors 30 and 40 attached to both ends of the panel 20 sense the generated ultrasonic waves and track the poison of the pen 10, so that data or information is input to the computer.

However, since the conventional pen type computer input apparatus using the ultrasonic waves has the ultrasonic generator to generate the ultrasonic waves in the middle of the pen, there occurs an error of the position of pen input to the computer, the position being different from a user's intension. Further, there also occurs a problem in that a movement of the pen less than the wavelength of the ultrasonic wave generated cannot be sensed.

### DISCLOSURE OF THE INVENTION

Therefore, an object of the present invention is to provide an input apparatus using ultrasonic waves and position recognition method thereof, capable of recognizing a precise position of the input apparatus using inertia in an input apparatus using ultrasonic waves.

According to an aspect of the present invention, there is provided an information input apparatus including an input unit for generating an ultrasonic signal and input a position and a receiver for receiving the ultrasonic signal generated in the input unit, wherein the input unit includes ultrasonic generator for generating an ultrasonic signal according to a movement of the input unit, and a controller for generating a control signal to enable the ultrasonic generator to generate the ultrasonic waves, and the receiver includes an ultrasonic receiver for receiving the ultrasonic signal generated in the ultrasonic generator, and a signal processor for performing a signal processing in a phase sensitive cross-correlation scheme in order to track the position of the input unit using the ultrasonic signal received in the ultrasonic receiver.

The information input apparatus using ultrasonic waves in accordance with an embodiment of the present invention can sense a movement of the input unit which is much less than the wavelength of the generated ultrasonic signal by tracking the position of the input unit in the phase sensitive cross-correlation scheme and so an error for a noise can be reduced. Further, frequency of the ultrasonic signal can be reduced through the phase sensitive cross-correlation scheme and the ultrasonic signal having the lowered frequency has a low loss in air.

According to another aspect of the present invention, there is provided an information input apparatus using ultrasonic waves, including an input unit for generating an ultrasonic signal and inputting a position and a receiver for receiving the ultrasonic signal generated in the input unit, wherein the input unit includes an ultrasonic generator for generating an ultrasonic signal according to a movement of the input unit, a first direction measurement unit for measuring the direction which the input unit is toward, and a controller for generating a control signal to enable the ultrasonic generator to generate the ultrasonic waves and the first direction measurement unit to measure the direction of the input unit, and the receiver includes an ultrasonic receiver for receiving the ultrasonic signal generated in the ultrasonic generator, a second direction measurement unit for measuring the direction which the receiver is toward, a direction calculator for calculating a relative direction vector between the input unit and the receiver using respective directions measured in the first and second direction measurement units, a signal processor for performing a signal processing in a phase sensitive cross-correlation scheme in order to track the position of the input unit using the ultrasonic signal received in the ultrasonic receiver, and a position tracking unit for tracking the position of the input unit tracked in the signal processor and the final position of the input unit from the relative direction vector between the input unit and the receiver produced in the direction calculator.

According to another embodiment of the present invention, an information input apparatus using ultrasonic waves tracks the position of the input unit in consideration of even directions of the input unit and the receiver, so that it can sense the movement of the input unit which is much less than the wavelength of generated ultrasonic signal, reduce an error caused by a noise, and track a precise position of the input unit. Further, frequency of the ultrasonic signal can be reduced through the phase sensitive cross-correlation scheme and the ultrasonic signal having the lowered frequency has a low loss in air.

According to yet another aspect of the present invention, there is provided a position recognition method of an information input apparatus using ultrasonic waves, including an input unit for generating an ultrasonic signal and input a position and a receiver for receiving the ultrasonic signal generated in the input unit, the method comprising the steps of: generating an ultrasonic signal according to a movement of the input unit; receiving the generated ultrasonic signal; measuring directions of the input unit and the receiver, respectively, and calculating a relative direction vector of the input unit and the receiver using the directions; performing a signal processing in a phase sensitive cross-correlation scheme in order to track the position of the input unit using the ultrasonic signal received in the ultrasonic receiver; and tracking the final position of the input unit from the position of the input unit tracked in the signal processor and the relative direction vector between the input unit and the receiver calculated in the calculating step.

According to the above method, an information input apparatus using ultrasonic waves tracks the position of the input unit in consideration of even directions of the input unit and the receiver, so that it can sense the movement of the input unit which is much less than the wavelength of generated ultrasonic signal, reduce an error caused by a noise, and track a precise position of the input unit. Further, frequency of the ultrasonic signal can be reduced through the phase sensitive cross-correlation scheme and the ultrasonic signal having the lowered frequency has a low loss in air.

### BRIEF DESCRIPTION OF THE DRAWINGS

The above objects, other features and advantages of the present invention will become more apparent by describing the preferred embodiment thereof with reference to the accompanying drawings, in which:

FIG. 1 is a view showing a configuration of a pen type computer input apparatus using ultrasonic waves in the prior art;

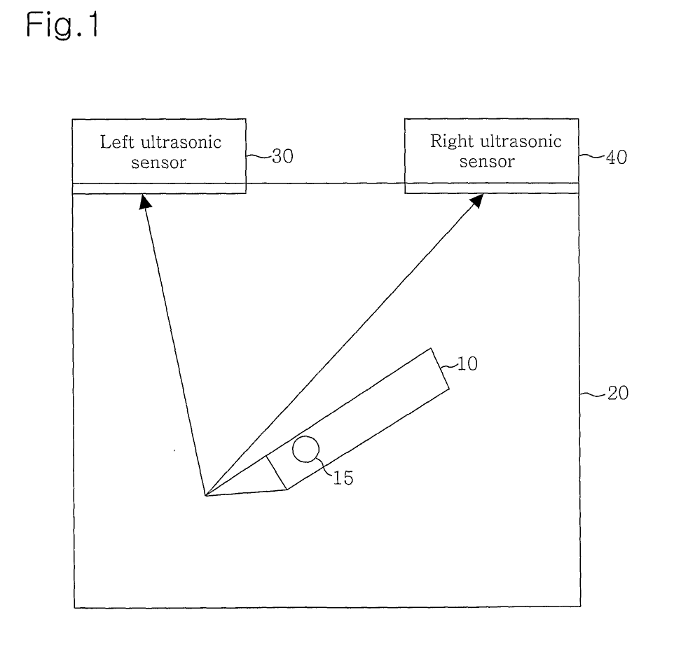

FIG. 2 is a view showing a schematic configuration of an information input apparatus using ultrasonic waves in accordance with an embodiment of the present invention;

FIG. 3 is a view showing a block configuration of an information input apparatus using ultrasonic waves in accordance with an embodiment of the present invention;

FIG. 4 is a flowchart illustrating an operation of an information input apparatus using ultrasonic waves in accordance with the present invention; and

FIG. 5 is a flowchart illustrating procedures to track the position of an input unit using a phase sensitive cross-correlation in accordance with an embodiment of the present invention.

### BEST MODE FOR CARRYING OUT THE INVENTION

Reference will now be made in detail to a preferred embodiment of the present invention, examples of which are illustrated in the accompanying drawings. In the description of the present invention, in the case that it is determined that a detailed description for related known function or configuration unnecessarily makes the present invention unclear, it will be omitted.

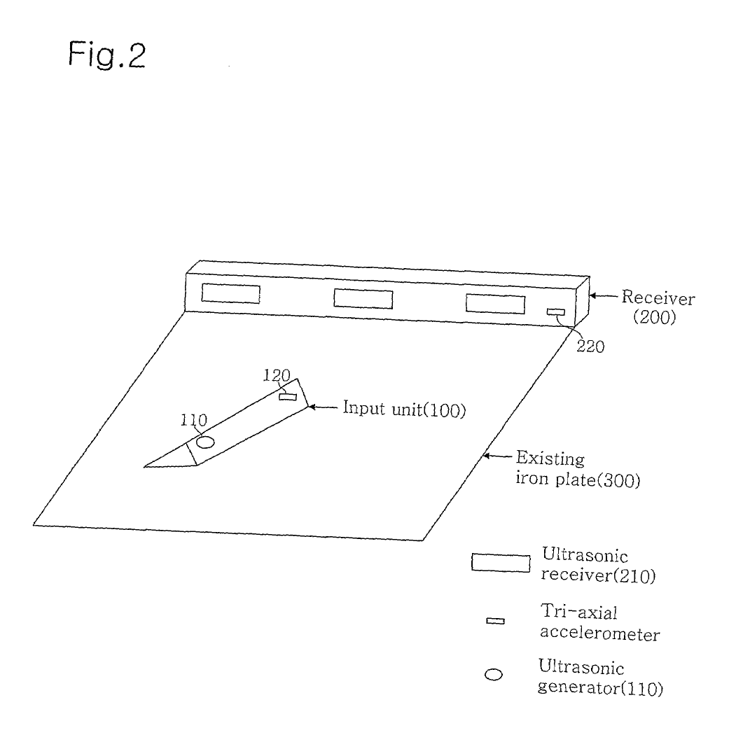

FIG. 2 is a view showing a schematic configuration of an information input apparatus using ultrasonic waves in accordance with an embodiment of the present invention, wherein the description will be given on the assumption that input means is a pen type. For reference, in the case of input means of glove type, it may be a glove type holding the entire hand or a finger mouse type where only one or a few fingers are inserted into the glove and used.

Referring to FIG. 2, the information input apparatus using ultrasonic waves generally includes an input unit 100 generating an ultrasonic signal and inputting a position, and a receiver 200 receiving the ultrasonic signal generated in the input unit 100.

The input unit 100 includes an ultrasonic generator 110 generating the ultrasonic signal, and a first direction measurement unit 120 measuring a direction which the input unit 100 is toward. The second receiving unit 200 being an long rod attachable to a fixed part of an existing iron plate 300 includes an ultrasonic receiver 210 receiving an ultrasonic signal generated in the ultrasonic generator 110, and a second direction measurement unit 220 measuring a direction which the receiving unit 200 is toward.

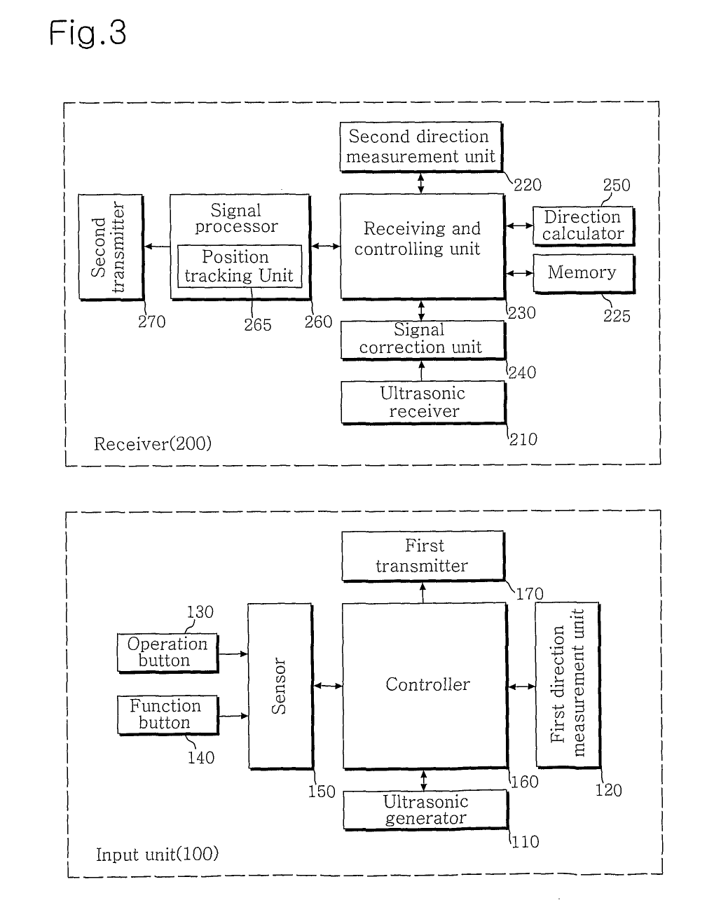

Meanwhile, FIG. 3 is a view showing a block configuration of an information input apparatus using ultrasonic waves in accordance with an embodiment of the present invention. As shown in FIG. 3, an input means 100 includes an ultrasonic generator 110, a first direction measurement unit 120, an operation button 130, a function button 140, a sensor 150, a controller 160, and a first transmitter 170.

The ultrasonic generator 110 generates an ultrasonic signal to track the position of the input unit 100, which operates when a user pushes the operation button 130.

The first direction measurement unit 120 measures the direction which the input unit 100 is toward. The first direction measurement unit 120 uses a tri-axial accelerometer to measure the direction which the input unit 100 is toward, and a measured direction vector of the input unit 100 together with a direction vector of the receiver 200 measured in the second direction measurement unit 220 to be described is used to measure a relative direction vector between the input unit 100 and the receiving unit 200.

The operation button 130 is used to operate the input unit 100. When the user pushes the operation button 130, the sensor 150 senses the push operation and operates the input unit 100. Further, the thickness of line input from the input unit 100 depends on the pressure induced on the button 130. First, when the user pushes the operation button 130 attached to the input unit 100 once, the input unit 100 starts to operate so as to generate the ultrasonic signal and the position of the input unit 100 is input to the computer.

Further, when the user pushes the operation button 130 three times, the thickness of line inputted to the computer is different each designated step. Such designated step may be two or three steps according to the strength of the pressure, and includes a step to stop the operation of the input unit 100.

The function button 140 is consisted of one or two buttons, which is designed to perform a specific function such as a function of left or right button of the existing mouse. So, when the user pushes the functional button 140, the sensor 150 connected thereto senses the push operation and performs a specific function designated according to a result of the sensing. The sensor 150 used here can be embodied as a pressure sensor or a thermal sensor.

The controller 160 outputs a control signal in order that the ultrasonic generator 110 generates an ultrasonic signal and the first direction measurement unit 120 measures the direction which the input unit 100 is toward.

The first transmitter 170 transmits the ultrasonic signal generated in the ultrasonic generator 110 to an outside of the input unit 100, and the ultrasonic signal transmitted externally through the first transmitter 170 is received in the ultrasonic receiver 210 of the receiver 200.

Meanwhile, the receiver 200 receives the ultrasonic signal generated in the input unit 100 so as to track the position of the input unit 100, and transmits the tracked position to the computer.

Such a receiver 200 includes the ultrasonic receiver 210, the second direction measurement unit 220, the memory 225, the receiving and controlling unit 230, the signal correction unit 240, the direction calculator 250, the signal processor 260, the position tracking unit 265, and the second transmitter 270.

The ultrasonic receiver 210 receives the ultrasonic signal generated in the ultrasonic generator 110. More than 3 ultrasonic receivers 210 included in the receiver 200 track a specific position of the input unit 100.

The second direction measurement unit 220 measures the direction which the receiver 200 is toward. Such second direction measurement unit 220 uses the tri-axial accelerometer to measure the direction which the receiver 200 is toward, and a direction vector of the receiver 200 measured together with a direction vector of the input unit 100 which has been measured is used to measure a relative direction vector between the input unit 100 and the receiver 200.

The reason to measure the relative vector between the input unit 100 and the receiver 200 is to track a precise position of the input unit 100. Here, since the ultrasonic generator 110 generating the ultrasonic waves is not positioned at the end of the input unit 100, there occurs an error to which an actual position based on the user's intension is not inputted, when tracking the position of the input unit 100.

Therefore, the position of the end of the input unit 100 can be precisely measured when making a calculation using the relative direction vector between the input unit 100 and the receiver 200 measured in advance and a value of the distance between the end of the input unit 100 and the ultrasonic generator 110 which is a predetermined distance away from the input unit 100 by applying trigonometry in order to correct such an error.

The receiving and controlling unit 230 outputs a control signal to enable the second direction measurement unit 220 to measure the direction of the receiver 200, and the position tracking unit 265 of the signal processor 260 to track the correct position of the input unit 100.

The signal correction unit 240 corrects the received ultrasonic signal. Such a correction unit 240 may be a time-gain control pre-amplifier, which performs a time-gain control based on received time of the ultrasonic signal received in the ultrasonic receiver 210 and corrects the ultrasonic signal.

The reason why the ultrasonic signal is corrected is that it is difficult for the ultrasonic receiver 210 to measure the ultrasonic waves unless correcting an attenuation occurring when the ultrasonic signal is exposed in air. At this time, the time-gain can be stored in the memory 225 in a formula format or a lookup table format.

The direction calculator 250 calculates a relative vector between the input unit 100 and the receiver 200 from the direction vector of the input unit 100 measured in the first direction measurement unit 120 and the direction vector of the receiver 200 measured in the second direction measurement unit 220.

The signal processor 260 performs the signal processing in a phase sensitive cross-correlation scheme in order to track the position of the input unit 100 (a position of the ultrasonic generator) using the ultrasonic signal received in the ultrasonic receiver 210. Such a phase sensitive cross-correlation scheme will be described in detail below.

The position tracking unit 265 tracks the final position of the input unit 100 (the position of the ultrasonic generator) using a position of the input unit 100 (the position of the ultrasonic generator) tracked in the signal processor 260, and a relative direction vector of the input unit 100 and the receiver 200 calculated in the direction calculator 250. At this time, the final position of the input unit 100 can be obtained by applying the trigonometry.

Finally, the second transmitter 270 transmits the final position of the input unit 100 tracked in the position tracking unit 265 to the computer.

Hereinafter, an operation of the information input apparatus using ultrasonic waves in accordance with the present invention will be described with reference to the accompanying drawings.

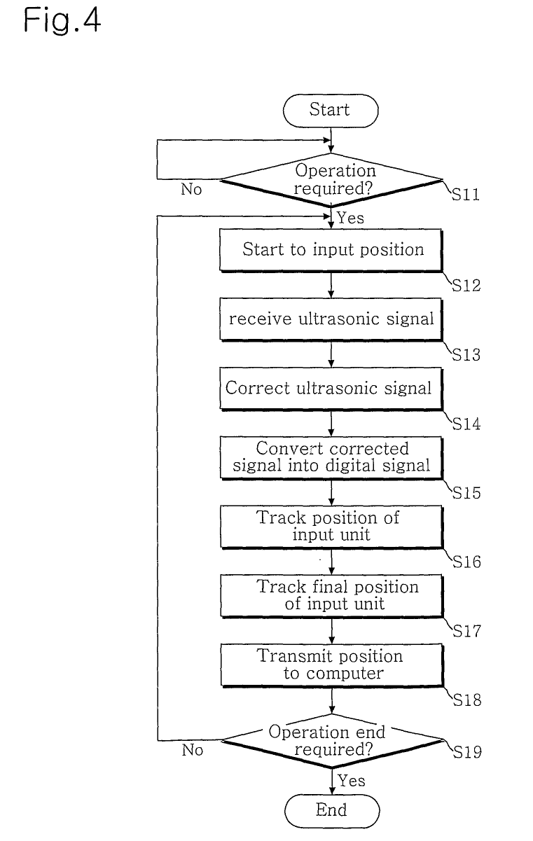

FIG. 4 is a flowchart illustrating an operation of an information input apparatus using ultrasonic waves in accordance with the present invention.

Referring to FIG. 4, the controller 160 checks whether or not the user requires to operate the input unit 100 through the operation button 130 (S11). When there is an operation requirement as a result of the checking, the controller 160 enables the ultrasonic generator 110 to generate the ultrasonic signal, and the first direction measurement to measure a direction where the input unit 100 is toward and to start a position input of the input unit 100 (S12). At this time, the first direction measuring unit 120 measures the direction using the tri-axial accelerometer.

The ultrasonic signal generated in the ultrasonic generator 110 is received in the ultrasonic receiver 210 of the receiver 200 (S13), and the received ultrasonic signal is corrected by the time-gain control pre-amplifier in the signal correction unit 240 (S14). At this time, the correction is performed by correcting a time-gain of the time-gain control pre-amplifier according to a receiving time of the received ultrasonic signal.

The corrected ultrasonic signal is converted into a digital signal (S15) and used to track the position of the input unit 100 (the position of the ultrasonic generating unit) through the phase sensitive cross-correlation scheme in the signal processor 260 (316). Further, the final position of the input unit 100 (the position of the end of the input unit) is tracked in the position tracking unit 265 by applying trigonometry using the tracked position of the input unit 100 (the position of the ultrasonic generator) and the relative direction vector of the input unit 100 and the receiver 200 calculated in the direction calculator 250 (S17).

Further, the final position of the input unit 100 (the position of the end of the input unit) tracked in advance is transmitted to the computer through the second transmitter 270 (S18). At this time, the second transmitter 270 and the computer can be connected through a universal serial bus (USB).

Finally, the receiving and controlling unit 230 checks whether or not there is an operational termination requirement of the input unit 100 (S19). And, when there is the operation termination requirement as a result of the checking, the operation is terminated, and the input unit 100 continues to perform the position input, otherwise.

Meanwhile, a detailed description of the phase sensitive cross-correlation scheme of the signal processor 260 will be given with reference to the accompanying drawings.

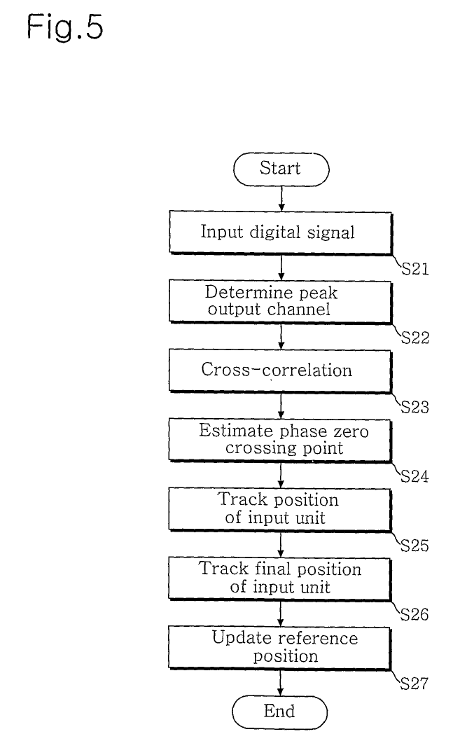

FIG. 5 is a flowchart illustrating procedures to track a position of the input unit using a phase sensitive cross-correlation in accordance with an embodiment of the present invention, wherein a digital signal converted from the received ultrasonic signal is inputted to the signal processor 260 and the final position of the input unit 100 is tracked.

Referring to FIG. 5, the receiving and controlling unit 230 enables the converted digital signal to be inputted to the signal processor 260 (S21), and determines the peak output channel from the inputted digital signal (S22). Further, the determined peak output channel and a reference signal are compared through the cross-correlation (S23), so that an approximate peak value used to track the position of the input unit 100 is found.

Further, a phase zero crossing value is estimated by finding the phase zero crossing point again (S24), and the position of the input unit 100 (the position of the ultrasonic generator) is tracked (S25). That is, the phase sensitive cross-correlation is a scheme to find the precise peak value used to make the position tracking by finding the phase zero crossing point again after the cross-correlation procedure.

Applying the trigonometry using the position of the input unit 100 (the position of the ultrasonic generator) tracked through the phase sensitive cross-correlation procedure and the relative direction vector between the input unit 100 and the receiver 200 calculated in the direction calculator 250, the final position of the input unit 100 (the position of the end of the input unit) is tracked (S26).

Further, the tracked final position of the input unit 100 (the position of the end of the input unit) is stored in the memory 225 as a reference signal to track a next position (S27).

Additionally, when tracking the position of the input unit 100, if the cross-correlation procedure only is performed, a sampling rate should be raised with an interpolation in order to find the peak value of the point used to track the position of the input unit 100 so that the amount of calculation increases and the value obtained also includes error elements due to the noise effect.

However, when using the phase sensitive cross-correlation scheme in the signal processing, an additional interpolation is not needed and accordingly the amount of relative calculation reduces so that it is possible to sense a movement of the input unit which is much smaller than a carrier wavelength and a signal to noise ration (SNR) increases.

As described above, in accordance with the present invention, the position of the input unit is precisely tracked using the ultrasonic waves together with the inertia, so the input can be precisely performed compared with an input unit for tracking the position of the input unit.

While the present invention has been described and illustrated herein with reference to the preferred embodiment thereof, it will be apparent to those skilled in the art that various modifications and variations can be made therein without departing from the spirit and scope of the invention. Thus, it is intended that the present invention covers the modifications and variations of this invention that come within the scope of the appended claims and their equivalents.

What is claimed is:

1. An information input apparatus including an input unit for generating an ultrasonic signal and a receiver for receiving the ultrasonic signal generated in the input unit, wherein
the input unit includes ultrasonic generator for generating an ultrasonic signal according to a movement of the input unit, and a controller for generating a control signal to enable the ultrasonic generator to generate the ultrasonic waves,
the receiver includes an ultrasonic receiver for receiving the ultrasonic signal generated in the ultrasonic generator, and a signal processor for performing a signal processing in a phase sensitive cross-correlation scheme in order to track the position of the input unit using the ultrasonic signal received in the ultrasonic receiver.

2. The information input apparatus according to claim 1, wherein the input unit is a pen or a glove type and further comprises an operation button used to operate the input unit or a function button used to perform a specific function.

3. The information input apparatus according to claim 2, wherein the operation button is operated by a user's pressure, and the thickness of the line inputted from the input unit depends on the strength of the pressure.

4. The information input apparatus according to claim 1, wherein the receiver includes 3 or more ultrasonic receivers which track a spatial position of the input unit.

5. The information input apparatus according to claim 1, wherein the receiver includes a signal correction unit to correct the ultrasonic signal by performing a time-gain control according to a receiving time of the ultrasonic signal received in the ultrasonic receiver.

6. An information input apparatus using ultrasonic waves, including an input unit for generating an ultrasonic signal and inputting a position and a receiver for receiving the ultrasonic signal generated in the input unit, wherein
the input unit includes an ultrasonic generator for generating an ultrasonic signal according to a movement of the input unit, a first direction measurement unit for measuring the direction which the input unit is toward, and a controller for generating a control signal to enable the ultrasonic generator to generate the ultrasonic waves and the first direction measurement unit to measure the direction of the input unit,
the receiver includes an ultrasonic receiver for receiving the ultrasonic signal generated in the ultrasonic generator, a second direction measurement unit for measuring the direction which the receiver is toward, a direction calculator for calculating a relative direction vector between the input unit and the receiver using respective directions measured in the first and second direction measurement units, a signal processor for performing a signal processing in a phase sensitive cross-correlation scheme in order to track the position of the input unit using the ultrasonic signal received in the ultrasonic receiver, and a position tracking unit for tracking the position of the input unit tracked in the signal processor and the final position of the input unit from the relative direction vector between the input unit and the receiver produced in the direction calculator.

7. The information input apparatus according to claim 6, wherein the input unit is a pen or a glove type and further comprises an operation button used to operate the input unit or a function button used to perform a specific function.

8. The information input apparatus according to claim 7, wherein the operation button is operated by a user's pressure, and the thickness of the line inputted from the input unit depends on the strength of the pressure.

9. The information input apparatus according to claim 6, wherein the receiver includes 3 or more ultrasonic receivers which track a spatial position of the input unit.

10. The information input apparatus according to claim 6, wherein the receiver includes a signal correction unit to correct the ultrasonic signal by performing a time-gain control according to a receiving time of the ultrasonic signal received in the ultrasonic receiver.

11. The information input apparatus according to claim 6, wherein the first and second direction measurement units measure directions using a tri-axial accelerometer.

12. A position recognition method of an information input apparatus using ultrasonic waves, including an input unit for generating an ultrasonic signal and input a position and a receiver for receiving the ultrasonic signal generated in the input unit, the method comprising the steps of:
generating an ultrasonic signal according to a movement of the input unit;
receiving the generated ultrasonic signal;
measuring directions of the input unit and the receiver, respectively, and calculating a relative direction vector of the input unit and the receiver using the directions;
performing a signal processing in a phase sensitive cross-correlation scheme in order to track the position of the input unit using the ultrasonic signal received in the ultrasonic receiver; and
tracking the final position of the input unit from the position of the input unit tracked in the signal processor and the relative direction vector between the input unit and the receiver calculated in the calculating step.

13. The method according to claim 12, wherein the measuring step includes the sub-step of measuring a direction using a tri-axial accelerometer.

14. The method according to claim 12, further comprising the step of correcting the ultrasonic signal by performing a time-gain control according to a receiving time of the ultrasonic signal received in the ultrasonic receiver
